(19) United States
(12) Patent Application Publication
(10) Pub. No.: US 2012/0100649 A1
(43) Pub. Date: Apr. 26, 2012

(54) METHOD FOR MANUFACTURING A FILM STRUCTURE

(76) Inventors: Young-Min KIM, Yongin-si (KR); Seon-Pil JANG, Seoul (KR); Bo-Sung KIM, Seoul (KR); Yeon-Taek JEONG, Seoul (KR); Yong-Su LEE, Hwaseong-si (KR); Tae-Young CHOI, Seoul (KR); Ki-Beom LEE, Seoul (KR); Kang Moon JO, Seoul (KR)

(21) Appl. No.: 13/100,149

(22) Filed: May 3, 2011

(30) Foreign Application Priority Data
Oct. 21, 2010 (KR) 10-2010-0103074

(51) Int. Cl. H01L 33/08; B05D 3/06; H01L 21/336; B05D 5/00; H01L 21/26; B05D 3/02; B05D 5/06

(52) U.S. Cl. 438/30; 427/559; 438/795; 438/158; 257/E21.328; 257/E33.053; 257/E21.414

(57) ABSTRACT

Provided is a method for manufacturing a film structure.

The method for manufacturing the film structure n includes forming a layer of a precursor material on a substrate, preheating the precursor material, and irradiating the precursor material with microwave radiation to form the film structure.

### CROSS-REFERENCE TO RELATED APPLICATION

This application claims priority to and the benefit of Korean Patent Application No. 10-2010-0103074 filed in the Korean Intellectual Property Office on Oct. 21, 2010, the entire contents of which are incorporated herein by reference.

### BACKGROUND OF THE INVENTION

(a) Field of the Invention

The present invention relates to a method for manufacturing a film structure.

(b) Description of the Related Art

Liquid crystal displays are presently one of the most widely used types of flat panel displays. Liquid crystal displays include two display panels on which field generating electrodes, such as a pixel electrode and a common electrode, are formed. A liquid crystal layer is interposed between the display panels.

The liquid crystal display displays an image by applying a voltage to the field generating electrodes to generate an electric field across the liquid crystal layer. The electric field determines the orientation of the liquid crystal molecules in the liquid crystal layer, which controls the polarization of incident light.

In addition to the field generating electrodes, the display panels of liquid crystal displays include a number of other elements, for instance thin film transistors, wirings, color filters, alignment layers and black matrices. To form such elements, various films may be formed on the display panel, or a photoresist film, which is used to make a pattern, may be formed or removed on the display panel.

For example, a semiconductor layer film used for a channel layer of a thin film transistor is typically formed. Films are also used to form the color filter, light blocking film, alignment layer and column spacer. In addition, a photoresist film may used to pattern gate lines and data lines, and then removed after the patterning is completed.

When a solution process (Sol-Gel method) is used as a method for forming a semiconductor layer film, heat treatment (annealing) at a high temperature is necessary.

Furthermore, the material used to make the color filter, the light blocking film, the alignment layer and the column spacer is generally formed of a solvent and a solid (monomer), and heat and light irradiation are necessary to remove the solvent and cure the monomer after the coating.

The above information disclosed in this Background section is only for enhancement of understanding of the background of the disclosure and therefore it may contain information that does not form the prior art that is already known to a person of ordinary skill in the art.

### SUMMARY OF THE INVENTION

When heat treatment or curing of a film structure in, for instance, a thin film transistor or a display device is performed by heat and light irradiation, outgassing occurs and/or productivity is reduced because of the excessive energy absorption.

A method for manufacturing film structure using a microwave by a low temperature process is provided.

In one aspect, a method for manufacturing the film structure includes forming a layer of a precursor material for a film structure on a substrate; preheating the precursor material; and irradiating the precursor material with microwave radiation.

The preheating of the precursor material may be performed at a temperature of 100 to 200° C.

The preheating of the precursor material may be performed using an infrared (IR) heater or by irradiating the precursor material with light.

The irradiating the precursor material with microwave radiation may be performed at a temperature of 350° C. or less.

The microwave radiation may have a frequency range of 300 MHz to 300 GHz.

The film structure may include a semiconductor, and forming a layer of precursor material for the film structure on a substrate includes using a solution process.

The film structure may include an organic film.

The organic film may be at least one of a color filter material, a light blocking film material, an alignment layer material, a photoresist film material, a column spacer material, an overcoat layer material and a spacer material.

The organic film may include an organic material including a dipole.

The organic film may include at least one of polystyrene, methyl methacrylate, methacrylic acid, hydroxyethyl methacrylate, ethyl 3-ethoxypropionate, propyleneglycol-monoethylether, cyclohexanone, propyleneglycol-monoethylether acetate (PGMEA), and polyimide.

In another aspect, a method for manufacturing a liquid crystal display is provided, including: forming a field generating electrode on at least one of a first substrate and a second substrate that faces the first substrate; forming an alignment layer on the field generating electrode; forming a liquid crystal layer including liquid crystal molecules and an alignment supplement agent between the first substrate and the second substrate; and forming an alignment polymer by irradiating the alignment layer and the liquid crystal layer with microwave radiation.

Before the forming of the alignment polymer, the method may further include preheating the alignment layer and the liquid crystal layer.

The preheating of the alignment layer and the liquid crystal layer may be performed at a temperature in the range of 100 to 200° C.

The irradiating of the alignment layer and the liquid crystal layer with microwave radiation may be performed at a temperature of 350° C. or less.

In the irradiating of the microwave to the alignment layer and the liquid crystal layer, the microwave may have a frequency range of 300 MHz to 300 GHz.

In yet another aspect, a method for manufacturing a thin film transistor is provided including: forming a gate line on a substrate; forming a gate insulating layer on the gate line; forming a layer of semiconductor precursor material on the gate insulating layer; preheating the semiconductor precursor material; forming a semiconductor layer by irradiating the preheated semiconductor precursor material with microwave radiation; and forming a source electrode and a drain electrode that face each other on the semiconductor layer.

The preheating of the semiconductor precursor material may be performed using an infrared heater or by irradiating the precursor material with light.

The irradiating of the microwave to the semiconductor precursor material may be performed at a temperature of 350° C. or less.

In the irradiating the semiconductor precursor material, the microwave may have a frequency range of 300 MHz to 300 GHz.

The semiconductor precursor material layer may be formed of an oxide semiconductor using a solution process.

The process may be performed at a low temperature by heat treating using a microwave, and efficiency may be improved by increasing heat absorption by irradiation of the microwave through preheating.

### BRIEF DESCRIPTION OF THE DRAWINGS

FIG. 1 is a schematic flowchart that illustrates a manufacturing method for a film structure according to an exemplary embodiment.

FIG. 2 is a top plan view that illustrates a thin film transistor according to another exemplary embodiment.

FIG. 3 is a cross-sectional view that is taken along the line of FIG. 2.

FIG. 4 is a graph that illustrates a device characteristic when the semiconductor is heat treated by using an infrared (IR) heater.

FIG. 5 is a graph that illustrates a device characteristic when the semiconductor is heat treated according to the exemplary embodiment of FIG. 2.

FIG. 6 is a cross-sectional view of a liquid crystal display according to yet another exemplary embodiment.

FIG. 7 is a graph that illustrates a thickness change that occurs in the course of forming the film structure according to the exemplary embodiment of FIG. 6.

FIG. 8 and FIG. 9 are schematic diagrams that illustrate a manufacturing method of a liquid crystal display according to still another exemplary embodiment.

### DETAILED DESCRIPTION OF THE EMBODIMENTS

Exemplary embodiments will be described more fully hereinafter with reference to the accompanying drawings.

As those skilled in the art would realize, the described exemplary embodiments may be modified in various different ways, all without departing from the spirit or scope of the present invention.

In the drawings, the thickness of layers, films, panels, regions, etc., are exaggerated for clarity.

When a layer is referred to as being “on” another layer or a substrate, it can be directly on another layer, or the substrate or a third intervening layer may also be present.

Throughout the specification, like reference numerals refer to like elements.

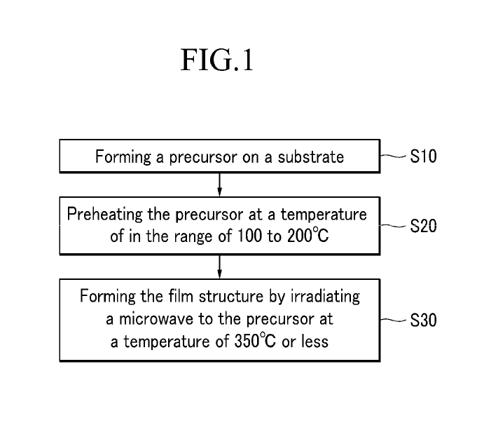

FIG. 1 is a schematic flowchart that illustrates a manufacturing method for a film structure according to an exemplary embodiment.

Referring to FIG. 1, a film is formed on a substrate by using a precursor material (S10).

The precursor material is the material (i.e. the chemical compounds) formed on the substrate before the chemical reaction that generates the film occurs. The precursor material includes the chemical compounds that participate in the chemical reaction to form the film. After the reaction, the film structure is formed on the substrate from the precursor.

For example, the precursor material may include a solvent and a solid.

The precursor material may be formed on the substrate by using a method such as spin coating or sputtering.

Then, the precursor material is preheated to a temperature in the range of 100 to 200° C. (S20).

The preheating of the precursor material may be performed using, for example, an infrared (IR) heater or irradiation of the precursor material with light, for example ultraviolet rays.

Then, the film structure is formed by irradiating the precursor material with microwave radiation at a temperature of 350° C. or less (S30). The microwave may have a frequency range of 300 MHz to 300 GHz.

Conventionally, when heat treatment is applied using a convection oven or a furnace, heat transfer may be performed through conduction from the outside surfaces of the device (for instance, the substrate) into the layer, such that heat is transferred to the film (precursor material) as the target by only applying heat to a substrate and the other structures at a predetermined temperature or higher. As a result, the thermal load applied to the substrate is relatively high and the amount of time needed for heating is long.

However, when, as in an exemplary embodiment, microwave radiation is used, heat energy is transferred to a polar molecular level. Thus, thermal load applied to the substrate or the other structures may be prevented.

The absorption of the microwave radiation by the precursor material depends on the temperature. As the temperature of the precursor material is increased, the absorption of microwave radiation by the precursor material is increased. Thus, according to exemplary embodiments, power loss in the process of heating the precursor material, as well as overall process time, may be reduced, and efficient heat treatment may be performed, by preheating the precursor material and the substrate at the temperature of 100 to 200° C. (S20 of FIG. 1) before the precursor material is irradiated with microwave radiation (S30 of FIG. 1).

The film structure according to an exemplary embodiment may be a semiconductor layer or an organic film.

A semiconductor layer may be formed by using the solution process (sol-gel method) to form a layer of semiconductor precursor material on the substrate. Heat treatment during the sol-gel formed precursor material may include irradiation with microwave radiation after the preheating the precursor material and substrate as set forth in FIG. 1 S20. The semiconductor precursor material layer may be formed of, for example an oxide semiconductor.

In addition, various other films may be formed using the method of the exemplary embodiments in order to form the display device.

Particularly, the color filter, the light blocking film, the alignment layer and the column spacer may be formed of an organic film, and the organic film may be mainly formed from a solvent and a solid (monomer). After each precursor material is coated on the substrate in order to form the organic film, instead of removing the solvent and curing the monomer by irradiation with heat from a convection oven or furnace, or ultraviolet rays, the precursor materials may be irradiated with microwave radiation after preheating according to the exemplary embodiment.

The precursor material used to form the organic film may be, for example, one or more of the materials that are represented by the following Formula 1 to Formula 9.

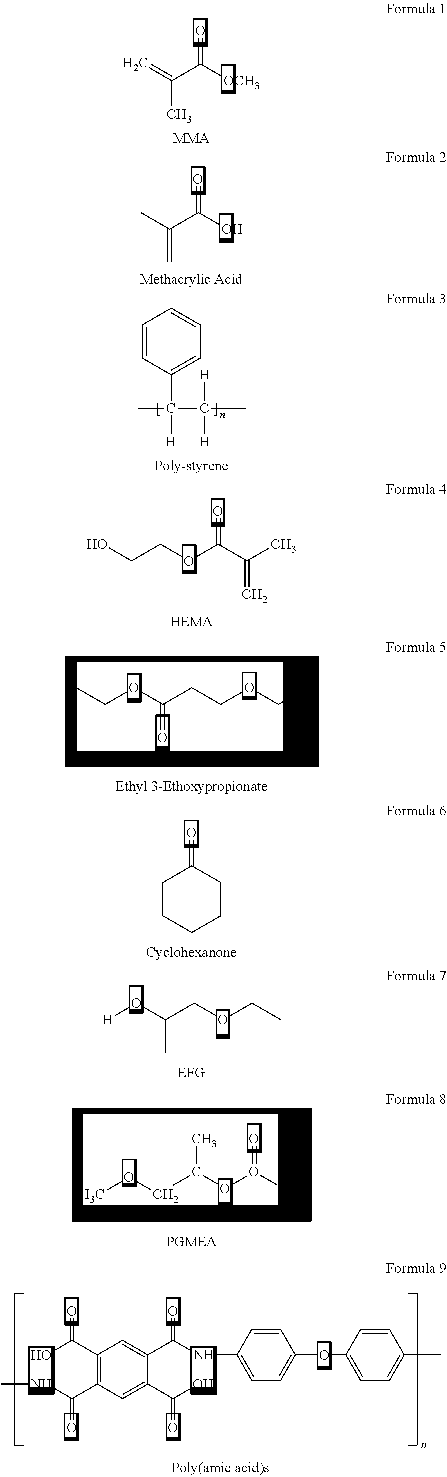

Formula 1 to Formula 9 represent the molecular structure of exemplary organic compounds that may be used as precursor materials to form organic films. In Formula 1 to Formula 9, the shaded portions indicate electric dipoles.

The electric dipole causes the molecule to align itself with an electromagnetic field. When the electromagnetic field oscillates, as it does when irradiated with microwave radiation, the electric dipole of the molecule continuously aligns with the oscillations, causing it to rotate (dipole rotation). The rotation of the dipole allows energy from the microwave radiation to be converted to heat, and the material to be very efficiently heated.

Therefore, as the number of dipoles is increased, it is possible to conduct more efficient heating.

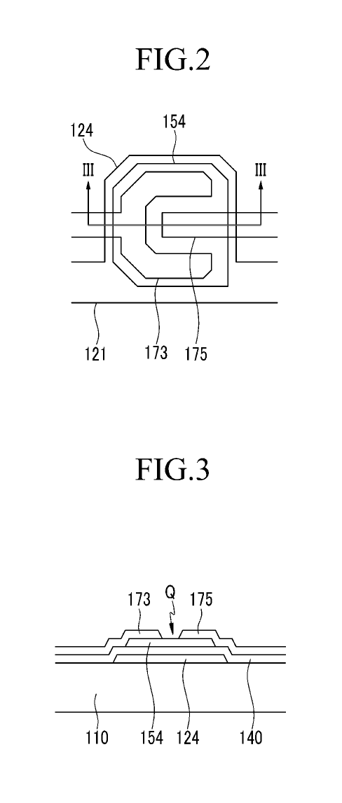

FIG. 2 is a top plan view that illustrates a thin film transistor according to another exemplary embodiment. FIG. 3 is a cross-sectional view that is taken along the line III-III′ of FIG. 2.

Referring to FIG. 2 and FIG. 3, the thin film transistor according to the exemplary embodiment is formed on the insulation substrate 110 and includes gate electrode 124 which branches off from gate line 121.

Gate line 121 may be made of, for example, aluminum-based metal, silver-based metal, copper-based metal, molybdenum-based metal, chromium (Cr), tantalum (Ta) and titanium (Ti), and may have a multilayer structure including two conductive layers that are different from each other.

Gate insulating layer 140 is formed on gate line 121 and gate electrode 124.

A semiconductor layer 154 is formed on the gate insulating layer 140.

Source electrode 173 and drain electrode 175 face each other and are formed on the semiconductor layer 154.

The channel of the thin film transistor is formed on the semiconductor layer 154 between source electrode 173 and drain electrode 175.

In the method for manufacturing the thin film transistor shown in FIG. 2 and FIG. 3, first, a gate line 121 including the gate electrode 124 is formed by layering and patterning the gate conductive layer with, for example, the aluminum-based metal, silver-based metal, copper-based metal, molybdenum-based metal, chromium (Cr), tantalum (Ta) and/or titanium (Ti) on the insulation substrate 110. A gate insulating layer 140 is then formed by layering silicon oxide (SiOx), silicon nitride (SiNx) or an organic insulator on the gate line 121.

Next, the semiconductor layer 154 is formed on the gate insulating layer 140. The semiconductor layer 154 is formed using the method described above with respect to FIG. 1, and the precursor material is preheated and then irradiated with microwave radiation. The semiconductor layer is then patterned.

The source electrode 173 and the drain electrode 175 are then formed by layering a conductive layer on the semiconductor layer 154, using a method such as sputtering, and then patterning the conductive layer to form the electrodes 173, 175.

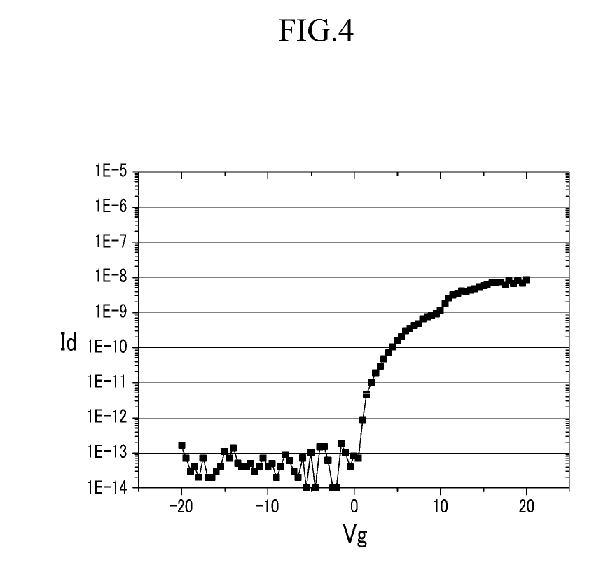

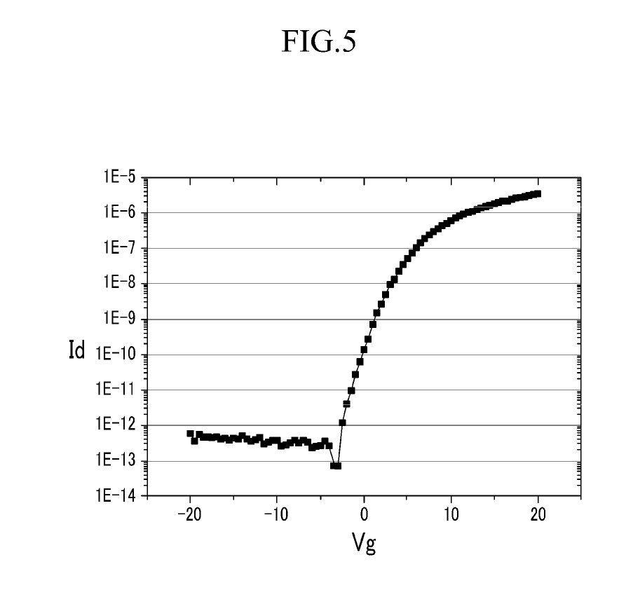

FIGS. 4 and 5 are graphs showing test results for a Comparative Example thin film transistor, formed using an IR heating method (FIG. 4), and an Example thin film transistor, formed using the method of the exemplary embodiments of FIG. 1 and FIG. 2 (FIG. 5).

In the Comparative Example thin film transistor (FIG. 4), the semiconductor layer of the thin film transistor was formed by first using a spin coating method to form a solution oxide semiconductor on the substrate. Then, an IR heat treatment process was performed at the temperature of 350° C. In the Example thin film transistor (FIG. 5), the semiconductor layer of the thin film transistor was formed by, first, using a spin coating method to form a solution oxide semiconductor precursor material on the substrate. Then, an IR heater was used to preheat the substrate and precursor material to 125° C. Next, the heat treatment process using microwave radiation was conducted for 10 min. For the microwave radiation heat treatment process, the VFM (variable frequency microwave) power of the microwave was 500 W and the temperature of the surface was 350° C.

Referring to FIG. 4 and FIG. 5, the graphs show drain current values (Id) when the gate is on (Vg is the gate voltage).

In comparing FIG. 4 and FIG. 5, the drain current value when the gate is on is greatly increased in the Example thin film transistor, in which the preheating was performed to the temperature of 100 to 200° C. before the heat treatment via microwave radiation per an exemplary embodiment, as compared to the Comparative Example thin film transistor, in which there was no preheating and the heat treatment was performed at 350° C. Thus, in the Example thin film transistor, as shown in FIG. 5, it can be seen that the characteristics of the device are improved.

Furthermore, in the case of Comparative Example thin film transistor of FIG. 4, in general, to obtain better device characteristics, the heat treatment should actually be performed at the temperature of 400° C. or more, causing even more heating of the device.

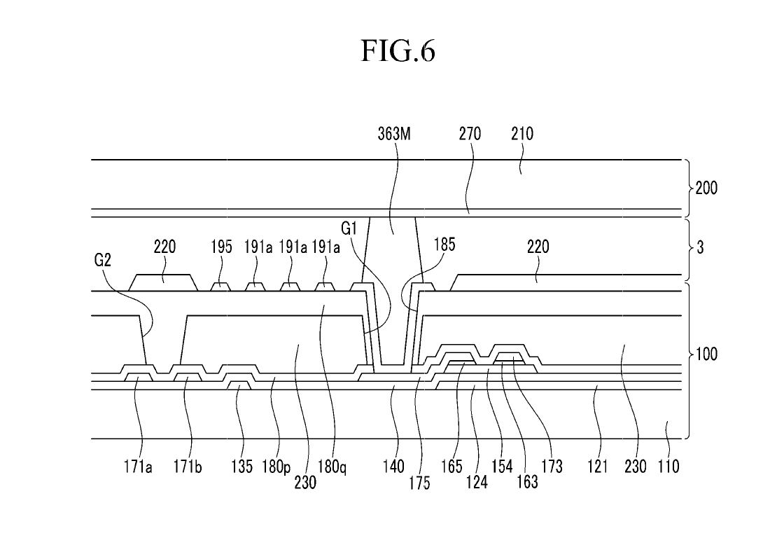

FIG. 6 is a cross-sectional view of a liquid crystal display according to yet another exemplary embodiment.

With reference to FIG. 6, the liquid crystal display according to an exemplary embodiment includes a lower display panel 100 and an upper display panel 200 that face each other, and a liquid crystal layer 3 that is disposed between the two display panels 100 and 200.

First, the lower display panel 100 will be described.

A gate line 121 and a storage electrode line 135 are formed on the insulation substrate 110.

The gate line 121 includes a gate electrode 124 for the thin film transistor.

A gate insulating layer 140 is formed on the gate line 121 and the storage electrode line 135, and a semiconductor layer 154 is formed on the gate insulating layer 140.

The semiconductor layer 154 is formed by using the film structure manufacturing method as described above with respect to FIG. 2 and FIG. 3.

Ohmic contacts 163 and 165 are formed on the semiconductor layer 154, and the ohmic contacts 163 and 165 may be made of a material such as n+ hydrogenated amorphous silicon in which silicide or n-type impurity is doped in a high concentration.

Data lines 171a and 171b and drain electrodes 175 are formed on the ohmic contacts 163 and 165 or gate insulating layer 140.

The data lines 171a and 171b include the source electrode 173 for the thin film transistor, and the source electrode 173 faces the drain electrode 175 with the gate electrode 124 disposed therebetween.

However, the shape and arrangement of the drain electrode 175 and the data lines 171a and 171b may be variously changed.

The gate electrode 124, the source electrode 173 and the drain electrode 175 form a thin film transistor (TFT) with the semiconductor layer 154.

The gate electrode 124, the source electrode 173 and the drain electrode 175 may be formed through a photo process, in which case a photoresist film may be used. The photoresist film may be formed of an organic film.

To form the photoresist film, organic photoresist precursor materials may be preheated to a temperature of 100 to 200° C. and then irradiated with microwave radiation at a temperature of 350° C. or less.

A lower passivation layer 180p that is made of silicon nitride or silicon oxide is formed on the data lines 171a and 171b, the drain electrode 175 and the semiconductor layer 154.

On the lower passivation layer 180p, a color filter 230 formed by a lithography method is formed.

The color filter 230 may be formed in a pixel area, and each color filter 230 may display any one of primary colors such as three primary colors of red, green and blue colors.

The left and right boundaries of the color filter 230 are disposed on the data lines 171a and 171b and may longitudinally extend along the data lines 171a and 171b.

In this case, the color filter 230 may have a band shape.

The color filters 230 having the same color are not adjacent each other.

The color filter 230 may have a structure including a pigment for implementing a color on a photosensitive organic composition.

For example, the color filter 230 includes red, green and blue color filters in which red, green, or blue pigments are included in a photosensitive organic composition.

In particular, the color filter 230 may have an opening G1 and a groove G2.

The opening G1 exposes the lower passivation layer 180p in a region where the drain electrode 175 and pixel electrode 191 are contacted.

The groove G2 is formed between the data lines 171a and 171b adjacent to each other between adjacent pixel areas.

In another exemplary embodiment, color filters 230 displaying different colors overlap between the data lines 171a and 171b adjacent to each other between adjacent pixel areas, and the groove G2 is not formed.

An upper passivation layer 180q that is formed of an organic material or an inorganic material is formed on the lower passivation layer 180p and the color filter 230.

The upper passivation layer 180q may protect the color filter 230 and planarize the layers formed at the lower part thereof.

The color filter 230 may be formed by curing precursor material that is formed of the solvent and the solid. The color filter 230 may include at least one of polystyrene, methyl methacrylate, methacrylic acid, hydroxyethyl methacrylate, ethyl 3-ethoxypropionate, propyleneglycol-monoethylether, cyclohexanone, propyleneglycol-monoethylether acetate (PGMEA), and polyimide.

The color filter 230 may be formed by preheating such precursor material at a temperature of 100 to 200° C. and then irradiating the precursor material with microwave radiation at a temperature of 350° C. or less in order to cure the precursor.

The upper passivation layer 180q has a contact hole 185 for exposing the drain electrode 175.

The contact hole 185 is connected to the opening G1 of the color filter 230.

On the upper passivation layer 180q, a pixel electrode 191 is formed.

The pixel electrode 191 may be made of a transparent conductive material such as, for example, ITO or IZO, or reflective metal such as, for example, aluminum, silver, chromium or an alloy thereof.

A light blocking member 220 is formed on the upper passivation layer 180q, and a spacer 363M is formed on the pixel electrode 191.

The light blocking member 220 is formed at a boundary of the pixel area and a portion corresponding to the thin film transistor.

However, it is the spacer 363M, and not the light blocking member 220, that is formed in the contact hole 185 where the pixel electrode 191 and the drain electrode 175 are contacted.

The spacer 363M fills the contact hole 185 and protrudes toward the upper display panel 200.

The spacer 363M maintains the interval between the upper display panel 200 and the lower display panel 100.

The spacer 363M may contact the upper display panel 200.

The light blocking member 220 and the spacer 363M may be formed simultaneously, and may be formed of material such as the colored organic film.

The light blocking member 220 is formed at a position that is lower than the spacer 363M.

Next, the upper display panel 200 will be described.

In the upper display panel 200, a common electrode 270 is formed on entire surface of a transparent insulation substrate 210, and an alignment layer (not shown) is formed on the common electrode 270.

The alignment layer may be formed of polyimide.

The alignment layer may be formed by forming a film of the alignment layer precursor on the common electrode 270, preheating the alignment layer precursor at the temperature of 100 to 200° C., and irradiating the alignment layer precursor with microwave radiation at the temperature of 350° C. or less as described above in the exemplary embodiment of FIG. 1.

The spacer 363M and the light blocking member 220 may be formed of an organic film.

After each precursor material is coated onto the substrate in order to form the organic film, it may be irradiated with microwave radiation, according to the exemplary embodiment of FIG. 1, instead of heating with a convection over or furnace, or irradiating with ultraviolet rays, in order to remove the solvent and cure the precursor material.

In the above exemplary embodiment, the light blocking member 220 is formed on the lower display panel 100, but the light blocking member 220 may be formed on the upper display panel 200.

The exemplary embodiment in which the light blocking member is formed on the upper display panel 200 will be described below.

The light blocking member 220 may be formed on the insulation substrate 210 at a boundary of the pixel area and a portion corresponding to the thin film transistor.

An overcoat layer may be formed on the light blocking member for planarization of the film.

A common electrode may be formed on the overcoat layer.

The overcoat layer may be formed of an organic film, and after each precursor material of the overcoat layer is coated onto the substrate in order to form the organic film, it may be irradiated with microwave radiation after the preheating according to the exemplary embodiment of FIG. 1.

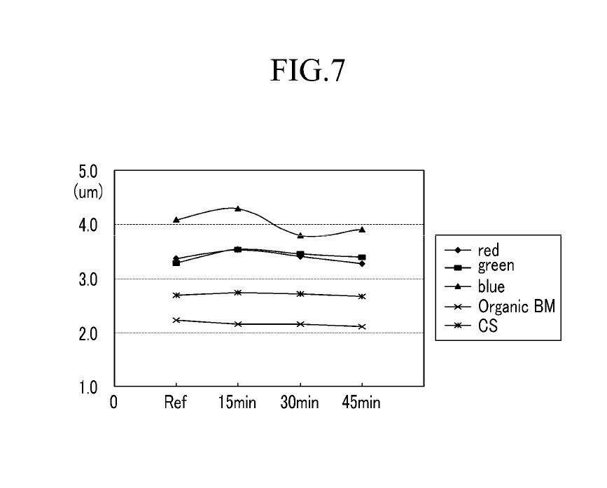

FIG. 7 is a graph that illustrates a thickness change in the course of forming the film structures according to the exemplary embodiment of FIG. 6.

FIG. 7 illustrates a thickness change according to the length of time the microwave radiation is irradiated to, in detail, the red color filter (red), the green color filter (green), the blue color filter (blue), the light blocking film (organic BM), and the column spacer (CS) corresponding to the spacer described in the exemplary embodiment.

The thicknesses of the light blocking film and the column spacer do not change as a function of irradiation time, and in the case of the color filter, there is only a slight thickness change or the change is in the error range of the measurement.

When the organic film structure is formed by irradiating with microwave radiation, it is possible to form a film having uniform thickness.

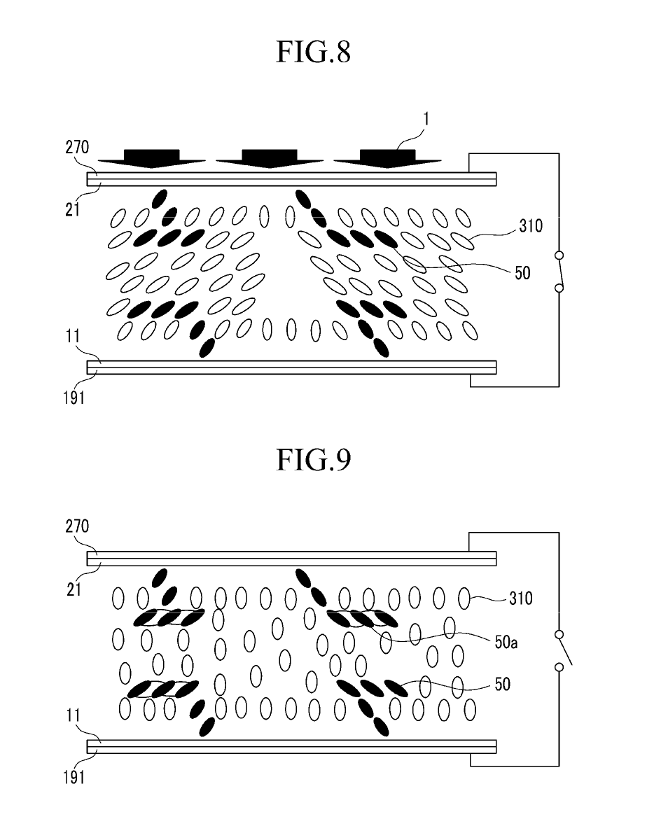

FIG. 8 and FIG. 9 are schematic diagrams that illustrate a manufacturing method of a liquid crystal display according to another exemplary embodiment.

In detail, FIG. 8 and FIG. 9 illustrate a method for forming a pretilt angle in liquid crystal molecules of the liquid crystal layer using an alignment supplement agent.

Referring to FIG. 8 and FIG. 9, the liquid crystal layer including the alignment supplement agent 50 and liquid crystal molecule 310 is disposed between the pixel electrode 191 and the common electrode 270.

Alignment layers 11 and 21 are disposed on the pixel electrode 191 and the common electrode 270.

The alignment layers 11 and 21 may be formed by at least one of generally-used materials for forming liquid crystal alignment layers, such as, for example, polyamic acid, polysiloxane or polyimide.

The liquid crystal molecules 310 are arranged in a vertical direction, i.e. perpendicular to the surfaces of pixel electrode 191 and the common electrode 270, when no voltage is applied to the electrodes (as indicated in FIG. 9). When a voltage is applied to the pixel electrode 191 and the common electrode 270, the liquid crystal molecules 310 and the alignment supplement agent 50 are inclined at a predetermined angle due to the application of the voltage across the liquid crystal layer (as indicated in FIG. 8).

To form the alignment layers having a pre-tilt angle, the liquid crystal layer, while voltage is applied to the pixel electrode 191 and the common electrode 270, the liquid crystal layer including the alignment supplement agent 50 and the liquid crystal molecules 310 are preheated at a temperature of 100° C. to 200° C. After the preheating, but still while applying the voltage to the electrodes, the alignment supplement agent 50 is polymerized by irradiating the liquid crystal layer including the alignment supplement agent 50 and the liquid crystal molecules 310 with microwave radiation 1 at the temperature of 350° C. or less.

The alignment supplement agent 50 may be, for example, a reactive mesogen (RM).

While practical exemplary embodiments have been described, it is to be understood that the invention is not limited to the disclosed embodiments, but, on the contrary, is intended to cover various modifications and equivalent arrangements included within the spirit and scope of the disclosure, including the appended claims.

What is claimed is:

1. A method for manufacturing a film structure, comprising:
forming a layer of precursor material for the film structure on a substrate;
preheating the precursor material; and
irradiating the precursor material with microwave radiation.

2. The method of claim 1, wherein:
the preheating of the precursor material is performed at a temperature of 100 to 200° C.

3. The method of claim 2, wherein:
the preheating of the precursor material is performed using an infrared heater or by irradiating the precursor material with light.

4. The method of claim 3, wherein:
the irradiating the precursor material with microwave radiation is performed at a temperature of 350° C. or less.

5. The method of claim 4, wherein:
the microwave radiation has a frequency range of 300 MHz to 300 GHz.

6. The method of claim 1, wherein:
the film structure includes a semiconductor, and forming a layer of precursor material for the film structure on a substrate includes using a solution process.

7. The method of claim 1, wherein:
the film structure includes an organic film.

8. The method of claim 7, wherein:
the organic film is at least one of a color filter material, a light blocking film material, an alignment layer material, a photoresist film material, a column spacer material, an overcoat layer material and a spacer.

9. The method of claim 7, wherein:
the organic film includes an organic material including a dipole.

10. The method of claim 7, wherein:
the organic film includes is at least one of polystyrene, methyl methacrylate, methacrylic acid, hydroxyethyl methacrylate, ethyl 3-ethoxypropionate, propyleneglycol-monoethylether, cyclohexanone, propyleneglycol-monoethylether acetate (PGMEA), and polyimide.

11. A method for manufacturing a liquid crystal display, comprising:
forming a field generating electrode on at least one of a first substrate and a second substrate that faces the first substrate;
forming an alignment layer on the field generating electrode;
forming a liquid crystal layer including liquid crystal molecules and an alignment supplement agent between the first substrate and the second substrate; and
forming an alignment polymer by irradiating the alignment layer and the liquid crystal layer with microwave radiation.

12. The method of claim 11, further comprising:
before the forming of the alignment polymer, preheating the alignment layer and the liquid crystal layer.

13. The method of claim 12, wherein:
the preheating of the alignment layer and the liquid crystal layer is performed at a temperature in the range of 100 to 200° C.

14. The method of claim 13, wherein:
the irradiating the alignment layer and the liquid crystal layer with microwave radiation is performed at a temperature of 350° C. or less.

15. The method of claim 14, wherein:
the microwave radiation has a frequency range of 300 MHz to 300 GHz.

16. A method for manufacturing a thin film transistor, comprising:
forming a gate line on a substrate;
forming a gate insulating layer on the gate line;
forming a layer of semiconductor precursor material on the gate insulating layer;
preheating the semiconductor precursor material;
forming a semiconductor layer by irradiating the preheated semiconductor precursor material with microwave radiation; and
forming a source electrode and a drain electrode that face each other on the semiconductor layer.

17. The method of claim 16, wherein:
the preheating of the semiconductor precursor material is performed using an infrared heater or by irradiating the precursor material with light.

18. The method of claim 17, wherein:
irradiating of the semiconductor precursor material with microwave radiation is performed at a temperature of 350° C. or less.

19. The method of claim 18, wherein:
the microwave radiation has a frequency range of 300 MHz to 300 GHz.

20. The method of claim 16, wherein:
the semiconductor precursor material layer is formed of an oxide semiconductor using a solution process.
